(19) United States
(12) Patent Application Publication
(10) Pub. No.: US 2005/0093135 A1
(43) Pub. Date: May 5, 2005

(54) Thermal dissipating element of a chip

(76) Inventors: Wei-Chi Liu, Ping-Tung City (TW); Wei-Feng Lin, Chu City (JP); Chung-Ju Wu, Kaohsiung City (JP)

Correspondence Address: LOWE HAUPTMAN GILMAN & BERNER, LLP;Suite 310, 1700 Diagonal Road, Alexandria, VA, 22314, US

(21) Appl. No.: 10/697,099

(22) Filed: Oct. 31, 2003

(51) Int. Cl. H01L 23/10; H01L 23/34

(52) U.S. Cl. 257/707; 257/713; 257/717

(57) ABSTRACT

The present invention relates to a thermal dissipating element of a chip to dissipate heat producing by operating the chip. The thermal dissipating element includes a top plate and a side plate, wherein the top plate curves and extends to be the side plate. The top plate includes a sink contacting with the chip.

### BACKGROUND OF THE INVENTION

1. Field of the Invention

The present invention relates to a thermal dissipating element of a chip, and more particularly, to a thermal dissipating element having a sink.

2. Description of the Prior Art

A chip packaging element always includes a thermal dissipating element to dissipate the heat produced by operating a chip. However, for protecting the wire bonds connecting a substrate and the chip thereon from being short circuit, the space between the thermal dissipating element and the substrate is full of an EMC, Epoxy Molding Compound. The heat produced by operating the chip is difficult to be conducted from the chip to the thermal dissipating element due to the low heat conductivity of the EMC. The reliability of the chip packaging element is reduced due to the mass heat that can not be conducted to the thermal dissipating element.

As shown in FIG. 1A, the prior chip packaging element includes a thermal dissipating element 11, a chip 18 and a substrate 19. The thermal dissipating element 11 includes a top plate 13, a side plate 15 and a sole plate 17. The top plate 13 curves and extendedly connects to the side plate 15. The side plate 15 curves and extendedly connects to the sole plate 17. The sole plate 17 contacts with and fastens on the substrate 19. The chip 18 electrical connects with the substrate 19 by wire bonds that are not shown in FIG. 1A. An EMC 191 is formed on the substrate 19, the thermal dissipating element 11 and the chip 18 to protect the thermal dissipating element 11 from the external force and protect the wire bonds from being short circuit.

There is a void or an air trap 193 formed inside the EMC 18. The air trap 193 effects the quality of the chip packaging element.

The air trap 193 appears during the packaging process for packaging the chip packaging element. During compressing the melting EMC 191 into the thermal dissipating element 11, the air trap 193 may be produced because air in the room is also compressed into the thermal dissipating element carelessly. The air trap 193 may be produced because water vapor and volatile composition of the EMC 191 being compressed into the thermal dissipating element 11 evaporates to be the air trap 193 during a follow-up heating step of the packaging process. The air trap 193 may also appear due to a lead-lag flow of the melting EMC 191 when the melting EMC 191 is compressed into the thermal dissipating element 11.

As shown in FIG. 1B, mold flow R of the EMC 191 is formed during the compressing process for compressing the EMC 191 into the thermal dissipating element 11 through the holes 151. The shape of the mold flow R is uniform before the EMC 191 contacting with the chip 18. The shape of the mold flow R′ is non-uniform while the EMC 191 contacting with the chip 18. A portion of the mold flow R′ contacting with the chip 18 lags while the other portion of the mold flow R′ that does not contact with the chip 18 remaining at the same velocity. Until the melting EMC 191 filling the thermal dissipating element 11 and being compressed out of the holes, the leading portion of the mold flow R′ surrounds the space among the lagged portion and the leading portion of the mold flow R′ to form the air trap 193.

The air trap 193 of the EMC 191 effects the reliability and the quality of the chip packaging element. When the chip 18 is tested or operated, the heat produced by the chip 18 expands the air trap 193 to raise the pressure inside the EMC 191. The EMC 191 may be broken to appear the popcorn condition due to the high pressure inside the air trap 193. The chip packaging element and the electrical element including the chip packaging element may be broken because of the popcorn condition. Besides, if there is vapor in the air trap 193, the ion of vapor inside the air trap 193 may corrode the chip 18 to reduce the period of validity of the chip packaging element. The mechanical strength and the thermal dissipating efficiency of the EMC 191 reduces because of the air trap 193. It is necessary to prevent the air trap 193 during compressing the melting EMC 191 and during the whole packaging process. Compressing the melting EMC 191 slower is an effective method for preventing the air trap 193 inside the EMC 191. However, the preventing method for compressing the melting EMC 191 slower lasts more than about 4-6 seconds during the whole packaging process.

According to the above description, it is necessary to develop an element to prevent the air trap inside the EMC and dissipate the heat more effectively.

### SUMMARY OF THE INVENTION

According to the above description of the background of the invention, it is one objective of the present invention to provide a thermal dissipating element of a chip of a chip packaging element to increase the heat dissipating efficiency and the area of dissipating heat by a sink.

It is another objective of the present invention to provide a thermal dissipating element of a chip of a chip packaging element to prevent the air trap for protecting the chip packaging element from broken.

It is a further objective of the present invention to provide a thermal dissipating element of a chip of a chip packaging element to prevent the air trap for remaining the mechanical strength and the reliability of the chip packaging element. The present thermal dissipating element also increases the period of validity of the chip packaging element.

It is a further objective of the present invention to provide a thermal dissipating element of a chip of a chip packaging element to increase the efficiency of the whole packaging process and reduce the time for compressing the melting packing material.

It is a further objective of the present invention to provide a thermal dissipating element of a chip of a chip packaging element to reduce the amount and the whole cost of a packing material.

It is a further objective of the present invention to provide a thermal dissipating element of a chip of a chip packaging element to increase the efficiency for recycling the recycled material having high heat conductivity.

The present invention provides a thermal dissipating element including a sink. The thermal dissipating element includes a top plate and a side plate, wherein the top plate curves and extendedly connects to the side plate. The top plate has the sink to contact with the chip to dissipate heat of the chip.

All these advantageous features as well as others that are obvious from the following detailed description of the preferred embodiments of the invention are obtained.

### BRIEF DESCRIPTION OF THE DRAWINGS

FIG. 1A is a sectional view of a chip packaging element in the prior art;

FIG. 1B is a schematic diagram of a compressing process in the prior art;

FIG. 2 is a sectional view of a thermal dissipating element of the first embodiment of the present art;

FIG. 3 is a sectional view of a chip packaging element of the first embodiment of the present art;

FIG. 4 is a sectional view of a chip packaging element of the second embodiment of the present art

FIG. 5 is a sectional view of a chip packaging element of the third embodiment of the present art; and

FIG. 6 is a schematic diagram of a compressing process in the present invention.

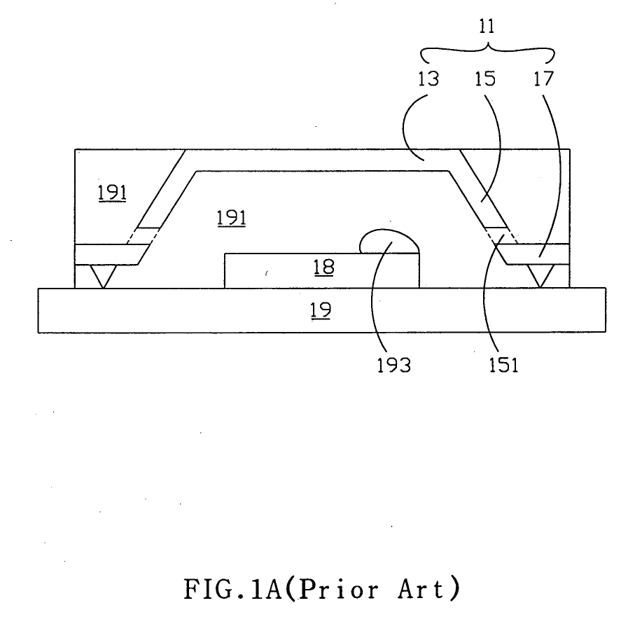

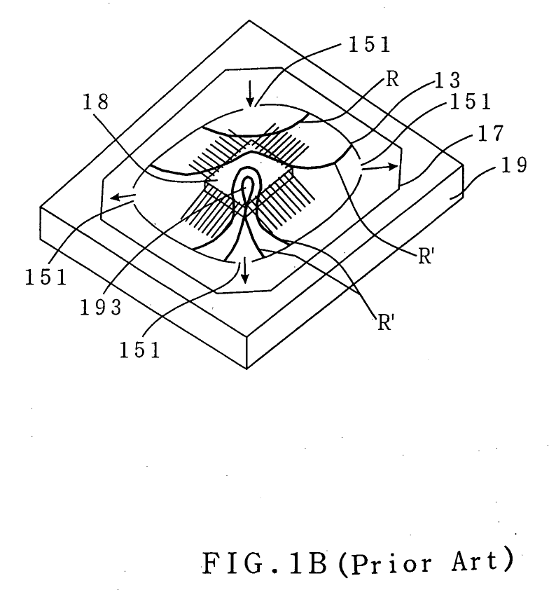

### DESCRIPTION OF THE PREFERRED EMBODIMENT

In the present disclosure, the words “a” or “an” are to be taken to include both the singular and the plural. Conversely, any reference to plural items shall, where appropriate, include the singular.

The preferred embodiments of the present invention provide a thermal dissipating element of a chip to improve the disadvantages of the prior art. Nonetheless, it should be recognized that the present invention can be practiced in a wide range of other embodiments besides those explicitly described, and the scope of the present invention is expressly not limited except as specified in the accompanying claims.

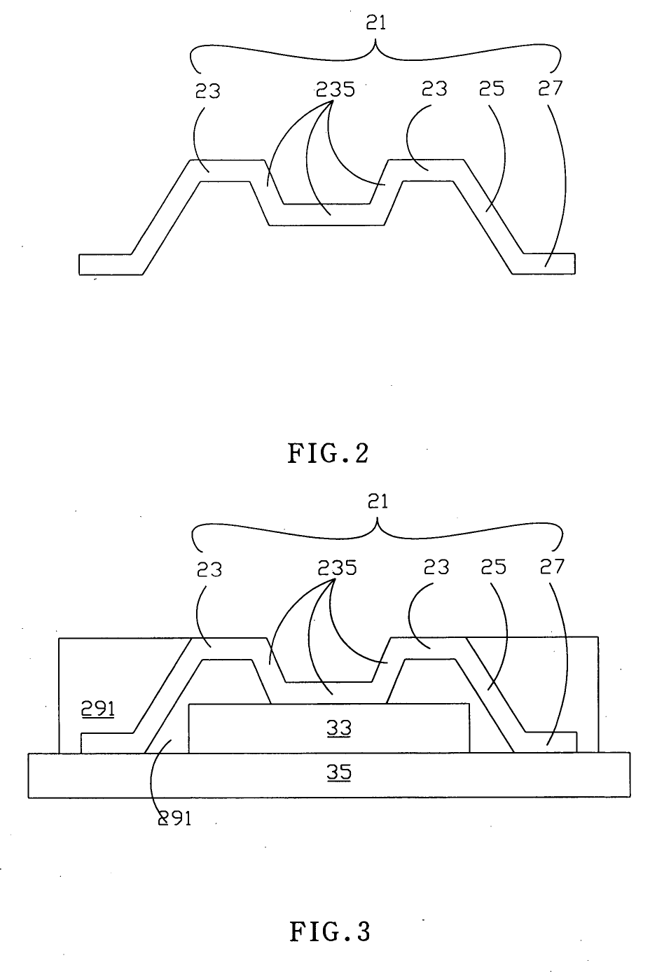

As shown in FIG. 2, a thermal dissipating element 21 includes a top plat 23, a side plate 25 and a sole plate 27. The top plate 23 curves and extendedly connects to the side plate 25 and has a sink 235. The side plate 25 curves and extendedly connects to the sole plate 27.

As shown in FIG. 3, the thermal dissipating element 21 of the present invention is fastened on a portion of a chip 33. The sole plate 27 is fastened on a substrate 35. The space on the chip 33 and the thermal dissipating element 21 is filled with a packing material 291 to protect the wire bonds connecting the chip 33 and the substrate 35 from being short circuit and protect the thermal dissipating element 21 from hitting by unexpected force, i.e. the external force. The packing material 291 may be the EMC or any kind of material having the similarly protecting properties.

The heat produced by operating the chip 33 is directly and fast dissipated by the surface of the sink 235 and the surface of the thermal dissipating element 21 due to the sink 235, which has high heat conductivity, contacting with the chip 33. The sink 235 is fastened on the chip 33 by an adhesive with high thermal conductivity. The sink 235 may be fastened on the chip 33 by another method if the method could conduct the heat more quickly and fasten the elements on each other better.

Comparing the chip packaging element with the present thermal dissipating element 21 and the prior chip packaging element, the thermal dissipating efficiency of the chip packaging element with the present thermal dissipating element 21 is obviously better than that of the prior chip packaging element. The only method for conducting heat produced by operating the chip 18 from the chip 18 to the top plate 13 is conducted through the EMC 191 having low thermal conductivity. Even though the whole thermal dissipating element 11 and the top plate 13 having high thermal conductivity, the mass heat produced by the chip 18 is difficult to be conducted from the chip 18 to the top plate 13 through the EMC 191. The present thermal dissipating element 21 including the sink 235 that has the high heat conductivity to conduct the heat produced by the chip 33 from the chip 33 to the whole thermal dissipating element 21 substantially increases the heat dissipating efficiency of the chip packaging element. Thus the heat dissipating efficiency of the prior chip packaging element is worse than that of the chip packaging element with the present thermal dissipating element 21. The reliability of the present chip packaging element is better than that of the prior chip packaging element because of the different between the sink 235 and the EMC 191. The heat produced by the chip 33 is dissipated well, so that the quality of operating the chip 33 remains well. Furthermore, the increased area of sink 235 of the thermal dissipating element 21 also increases the heat dissipating efficiency of the thermal dissipating element 21.

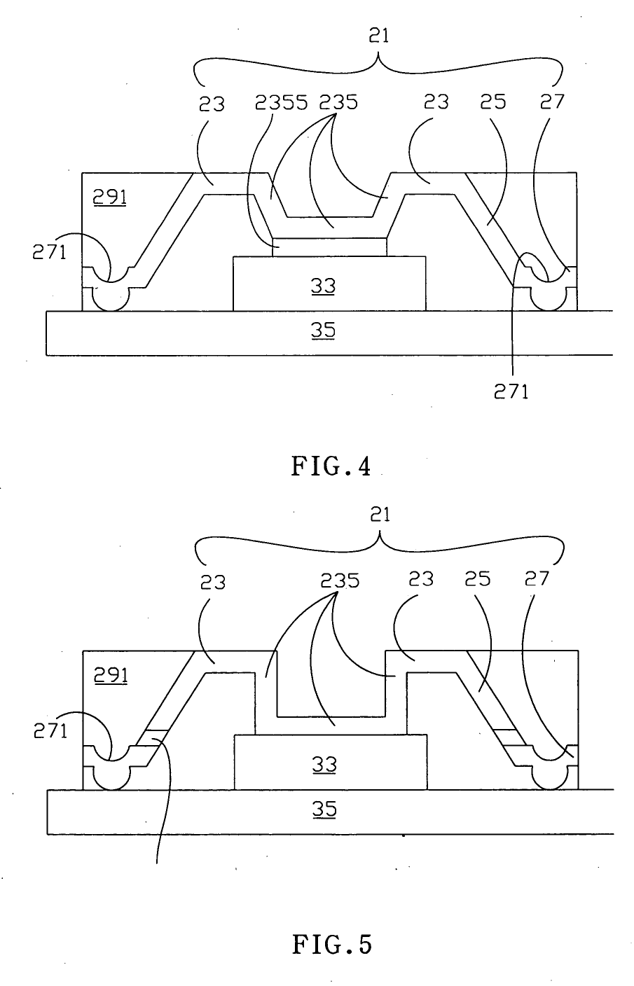

According to FIG. 4, the sole plate 27 of the second embodiment of the present invention includes a plurality of cavities 271. The sink 235 further includes a lump 2355 contacting with the chip 33. The lump 33 is fastened between the sink 235 and the chip 33. The chip 33 is fastened between the lump 2355 and the substrate 35. The lump 2355 may be a silicon chip. The material of the lump 2355 may also be metal, i.e. aluminum or copper, or something having high thermal conductivity. The heat producing by operating the chip 33 is conducts from the chip 33 to the thermal dissipating element 21 through the lump 2355 and the sink 235 having high thermal conductivity. Both the surface on the sink 235 and any portion of the thermal dissipating element 21 covered by anything dissipate the heat quickly. The lump 2355 is fastened between the thermal dissipating element 21 and the chip 33 by an adhesive with high thermal conductivity. The lump 2355 may be fastened on the chip 33 and the sink 235 by another method if the method could conduct the heat more quickly and fasten the elements on each other better.

Because the material of the lump 2355 is chosen from any solid having high heat conductivity, the present chip packaging element could also recycle the recycled material, i.e. the inferiority silicon chip, having high heat conductivity. If a recycled material is chosen to be the lump 2355, the complex recycling process for recycling the recycled material could be omitted and the recovery efficiency of the recycled material increases because of the present invention.

As shown in FIG. 5, the thermal dissipating element 21 of the third embodiment of the present invention includes a plurality of holes 251 between the side plate 25 and the sole plate 27. The packing material 291 filling the space between the thermal dissipating element 21 and the substrate 25 is compressed into the thermal dissipating element 21 through holes 251. The packing material 291 may be the EMC or something like that. The area of the sink 235 equals to the area of the chip 33 to conduct the heat produced by the chip 33 more quickly and more effectively. The area between the sink 235 and the chip 33 of the third embodiment is larger than the area between the sink 235 and the chip 33 of the above embodiments of the present invention. So that the heat produced by the chip 33 is dissipated more uniformly and more effectively through the sink 235 because of the sink 235 contacting with all of the chip 33.

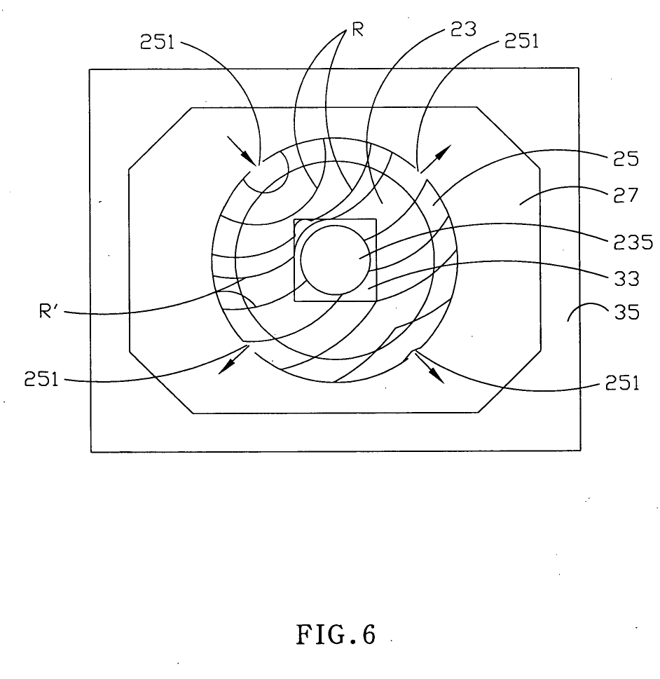

Moreover, mold flow R of the packing material 291 is formed during the compressing process for compressing the packing material 291 into the thermal dissipating element 21 through the holes 251, as shown in FIG. 6. The shape of the mold flow R is uniform before the packing material 291 contacting with the chip 33 and the sink 235. The shape of the mold flow R′ is non-uniform while the packing material 291 contacting with the chip 33 because of the velocity of the packing material 291 on the chip 33 being slower than the velocity of the packing material 291 beside the chip 33. However, the velocity of the packing material 291 becomes more uniform after the packing material 291 with the slower velocity contacting with the sink 235. The packing material 291 is compressed into the thermal dissipating element 21 until the packing material 291 filling the space inside the thermal dissipating element 21 and the space on the substrate 35 for protecting the whole chip packaging element. Until the compressing process stop, the air trap does not appear because the sink 235 adjusts the difference between the faster velocity and the slower velocity of the packing material 291. By the way, the shape of the sink 235 may be circular, as shown in FIG. 6, or quadrilateral as the chip 33.

The sink of the thermal dissipating element of the present invention reduces the packing material filled between the thermal dissipating element and the substrate and the time for compressing the packing material into the thermal dissipating element. For instance, a compressing process lasting about 12 seconds needs an extra time lasting about 4-6 seconds for preventing the air trap 193 inside the EMC 191 in the prior art. A compressing process for packaging the chip packaging element having the present thermal dissipating element needs the less amount and the less cost of the packing material and does not need the process for preventing the air trap. The whole compressing process becomes more quickly and more effectively due to the reduced amount of the packing material. The mechanical stress of the chip packaging element with the present thermal dissipating element having none of the air trap is much stronger than that of a chip packaging element including an air trap to increase the reliability and the period of validity of the chip packaging element. Moreover, the area for dissipating heat, the efficiency for recycling the recycled material having high heat conductivity and the efficiency for dissipating the heat produced by the chip increase due to the present invention.

The above description only demonstrates and illustrates the preferred embodiments of the present invention, but does not limit the scope of the present invention to what described detailed herein; and any equivalent variations and modifications of the present invention should be within the scope of the claims hereafter.

1: A thermal dissipating element of a chip, comprising:
a top plate including a sink; and
a side plate, said top plate curving and extendedly connecting to said side plate.

2: The thermal dissipating element according to claim 1, wherein said sink contacts with said chip.

3: The thermal dissipating element according to claim 1, wherein the shape of said sink is circular.

4: The thermal dissipating element according to claim 1, wherein the shape of said sink is quadrilateral.

5: The thermal dissipating element according to claim 1, wherein said sink further comprises a lump.

6: The thermal dissipating element according to claim 5, wherein said lump contacts with said chip.

7: The thermal dissipating element according to claim 5, wherein the shape of said lump is quadrilateral.

8: The thermal dissipating element according to claim 5, wherein the shape of said lump is selected from quadrilateral or circular.

9: The thermal dissipating element according to claim 5, wherein said lump is a silicon chip.

10: The thermal dissipating element according to claim 1, further comprising a sole plate to extendedly connect to side plate.

11: The thermal dissipating element according to claim 10, said side plate and said sole plate including a plurality of holes, said holes being formed between said side plate and said sole plate.

12: The thermal dissipating element according to claim 10, wherein said sole plate includes a plurality of cavities.

13: The thermal dissipating element according to claim 5, wherein the material of said lump is metal.

14: The thermal dissipating element according to claim 13, wherein the material of said lump is aluminum.

15: The thermal dissipating element according to claim 13, wherein the material of said lump is copper.

16: A chip packaging element, comprising:
a substrate;
a chip fastened on said substrate; and
a thermal dissipating element of said chip, said thermal dissipating element including a top plate, a side plate, and a sole plate, said top plate curving and extendedly connecting to said side plate, said side plate curving and extendedly connecting to said sole plate, said top plate having a sink, wherein said sole plate is fastened on said substrate.

17: The chip packaging element according to claim 16, wherein said sink is fastened on said chip, and said chip is fastened between said sink and said substrate.

18: The chip packaging element according to claim 17, wherein said sink contacts with all of said chip.

19: The chip packaging element according to claim 16, said sink further comprising a lump contacting between said sink and said chip, wherein said chip is fastened between said lump and said substrate.

20: The chip packaging element according to claim 19, wherein said lump is fastened on said sink by an adhesive with high thermal conductivity.
